(19) United States
(12) Patent Application Publication
(10) Pub. No.: US 2006/0258031 A1
(43) Pub. Date: Nov. 16, 2006

(54) Wafer-level electro-optical semiconductor manufacture fabrication method

(76) Inventors: Bily Wang, Hsin Chu City (TW); Jonnie Chuang, Pan Chiao City (TW); Chuan-Fa Lin, Shu Lin City (TW); Chi-Wen Hung, Chung Li City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/488,764

(22) Filed: Jul. 19, 2006

Related U.S. Application Data
(63) Continuation-in-part of application No. 11/041,952, filed on Jan. 26, 2005.

(51) Int. Cl. H01L 21/00

(52) U.S. Cl. 438/29; 438/460

(57) ABSTRACT

A wafer-level electro-optical semiconductor manufacture fabrication method improves upon traditional electro-optical semiconductor grain packaging methods. The present invention electrically connects semiconductor grains to the grains on a top surface of a wafer. This is done by either screen-printing or steel board-printing solder or silver paste onto the wafer. After that, the wafer is processed using the following steps: processing the devices, bonding with wire, packaging the wafer and finally cutting the wafer. Using this method raises the production yield while production times and costs are reduced. The wafer-level electro-optical semiconductor fabrication mechanism comprises: a wafer, an electro-optical semiconductor grain and conductive materials.

### CROSS-REFERENCE TO RELATED APPLICATIONS

This Application is a Continuation-in-Part of application Ser. No. 11/041952, filed on 26 Jan. 2005, and entitled WAFER-LEVEL ELECTRO-OPTICAL SEMICONDUCTOR MANUFACTURE FABRICATION MECHANISM AND A METHOD FOR THE SAME.

### BACKGOUND OF THE INVENTION

1. Field of the Invention

The present invention relates to a semiconductor manufacture fabrication method, and more particularly, to a wafer-level electro-optical semiconductor manufacture fabrication method.

2. Description of Related Art

Fabrication factories are always researching new ways and methods to increase the production capacity of their electro-optical semiconductor packaging production lines. Most improvements are related to either process flows or are made through the deployment of new materials that lower production costs or have faster production times. Process flow improvement is a very important subject. Owing to the precise machinery needed for grain packaging, the machinery is difficult to redesign and doing so is very expensive. As such, improving the process flow is relatively cheap and easily achievable.

IC substrates, such as BGA boards, CSP boards and flip chips, have all undergone vast improvements over recent years. Portable electric products are also becoming smaller and thinner, so IC substrates require thinner lines and smaller holes for their products.

Please refer to FIG. 1, which shows a traditional LED package mechanism 1a, and a substrate 10a connected to an LED 12a and a wire 14a, all packaged by a packaging material 16a. During the fabrication stage, there are many complex processes and efficiency problems with the traditional LED package mechanism 1a often occur. In practice, the package 1a affects the package's size, the product's performance and the yield. The traditional RGB grains cannot be set close together because the traditional line width is too wide. Consequently, the light that is emitted will not be very bright. The same problem is also encountered in the sensor-packaging field.

### SUMMARY OF THE INVENTION

The major object of the present invention relates to a wafer-level electro-optical semiconductor manufacture fabrication method. It provides a new mechanism for use in electro-optical semiconductor packaging processes that lowers fabrication costs. The present invention can be used with an automatic semiconductor mechanism to provide low-cost, high-quality products with electro-optical semiconductor grain packaging applications.

The second object of the present invention is to provide a wafer-level electro-optical semiconductor manufacture fabrication method that produces the thin electrical lines and tiny fabrication structures needed for IC substrates.

The third object of the present invention is to provide a wafer-level electro-optical semiconductor manufacture fabrication method that can plant a demand module circuit in advance in the wafer thereby reducing the electro-optical device's volume. This will allow a single chip to be made into a module type chip or packaged into a semiconductor device.

The forth object of the present invention is to provide a wafer-level electro-optical semiconductor manufacture fabrication method, which dissipates heat better than current mechanisms by using a wafer substrate.

The fifth object of the present invention is to provide a wafer-level electro-optical semiconductor manufacture fabrication method, which cuts different sizes monitors. The monitors can cut a single unit LED to remove bad points thereon.

To achieve the objects mentioned above, the manufacture fabrication method of the present invention comprises the steps as follows: preparing a wafer with a preservation position for covering the jointed crystal grains; daubing a plurality of conductive materials onto the preservation position; stacking electro-optical semiconductors onto the conductive materials of the wafer; packaging the electro-optical semiconductor with a highly polymeric material to produce a semi-finished product; cutting the semi-finished product to form different sizes or a single unit electro-optical semiconductor mechanism.

The above summaries are intended to illustrate exemplary embodiments of the invention, which will be best understood in conjunction with the detailed description to follow, and are not intended to limit the scope of the appended claims.

### BRIEF DESCRIPTION OF THE DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows a traditional LED package structure diagram.

FIG. 2 shows a top view diagram of the traditional LED package structure.

FIG. 3 show a top view diagram of the wafer level electro-optical semiconductor fabrication mechanism.

FIG. 4 shows a sectional diagram of the connection of the electro-optical semiconductor grain and wafer of the present invention.

FIG. 5 shows a top view diagram of a RGB grain module of the present invention.

FIG. 5A shows a top view diagram of directly fabricating the RGB grain module of the present invention.

FIG. 6 shows another embodiment of the present invention.

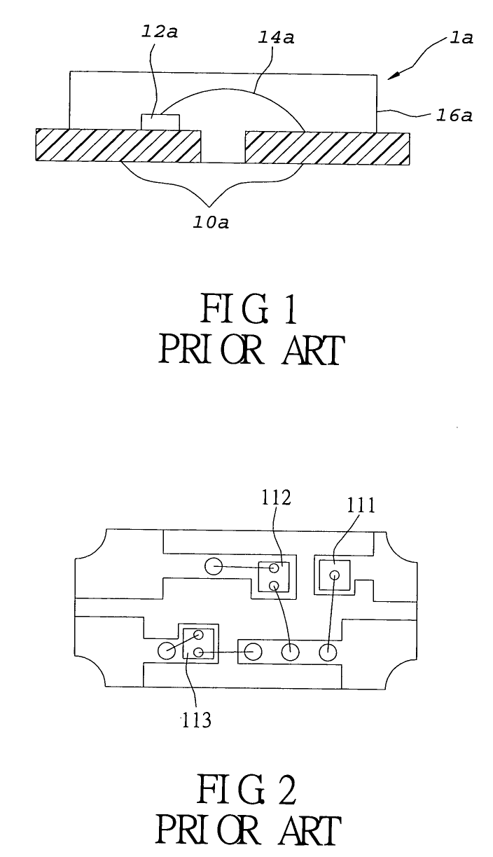

### DETAILED DESCRIPTION OF PREFERRED EMBODIMENTS

The present method prints conductive materials onto the wafer, or a gold or tin projective block to simplify the grain-pasting step in the manufacturing method of an electro-optical semiconductor. The method of the present invention comprises the following steps: producing the wafer; setting the conductive material; stacking the electro-optical grain on top of the wafer (thereby eliminating the need for a bonding line, which is usually made of gold); and finally packaging and cutting the electro-optical semiconductor. By printing the conductive materials onto the wafer, fewer distortions occur and the alignment of the material is improved. As such, the electro-optical semiconductor grain can be laid more easily. Compared with the peripheral assistant machine, the present invention is a more economical semiconductor grain packaging production system. It can also be used to place Zener diodes, over-voltage protection, voltage regulation, current regulation, noise filtering and electrical static discharge circuits upon the wafer in advance to improve the entire functioning of the electro-optical semiconductor.

The present invention comprises: a wafer 10 with a top surface and a back surface; the top surface having a plurality of preservation positions for covering the jointed crystal grains and electro-optical semiconductor grains, and also has crystal joints which match the preservation positions. There are also conductive materials in the top surface of the wafer 10. The electro-optical semiconductor can be an LED or an image sensor.

The manufacturing method of the present invention comprises the following steps: preparing a wafer 10 with a preservation position 18 for the grain joints; placing a conductive material 13 onto a preservation position 18; stacking electro-optical semiconductor grains 12 onto the conductive materials 13 of the wafer 10; packaging the electro-optical semiconductor grains 12 with highly polymeric materials to create a semi-finished product; cutting the semi-finished product to form different sizes or a single unit electro-optical semiconductor mechanism.

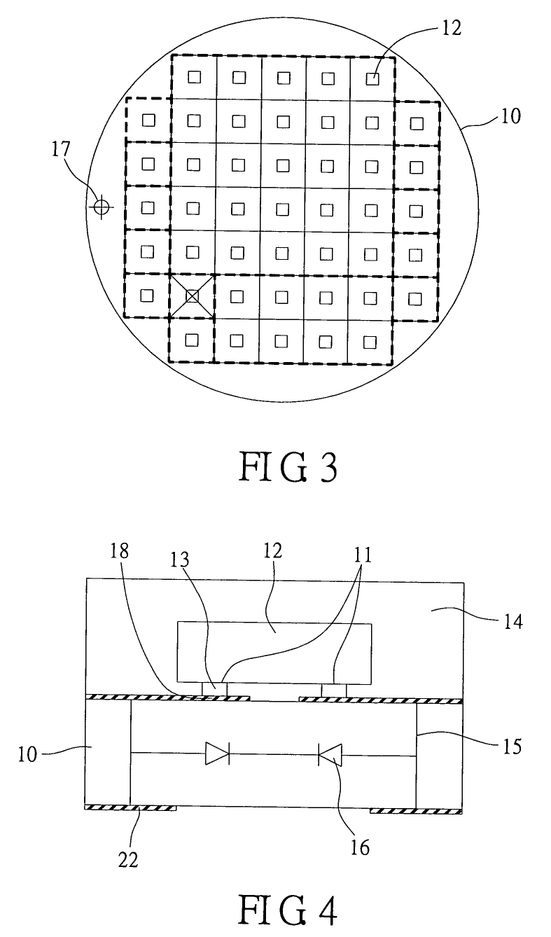

FIG. 3 shows a top view diagram of an embodiment of the present invention wherein the top surface of the wafer 10 has a plurality of electro-optical semiconductor grains 12. FIG. 4 shows a sectional drawing of the electro-optical semiconductor grains 12 and the wafer 10. FIG. 4 shows a wafer 10 which has a top surface and a back surface, the top surface has a preservation position 18 for covering jointed crystal grains; the electro-optical semiconductor grains 12, which have a plurality of crystal joints 11 electrically connected to the preservation position 18; the conductive materials 13 which are located upon the top surface of the wafer 10 electrically connect to the electro-optical semiconductor grains 12. Furthermore, the wafer 10 can cut different sized monitors (dotted lines). The monitors can cut a single unit LED (dotted line) to remove bad points thereon.

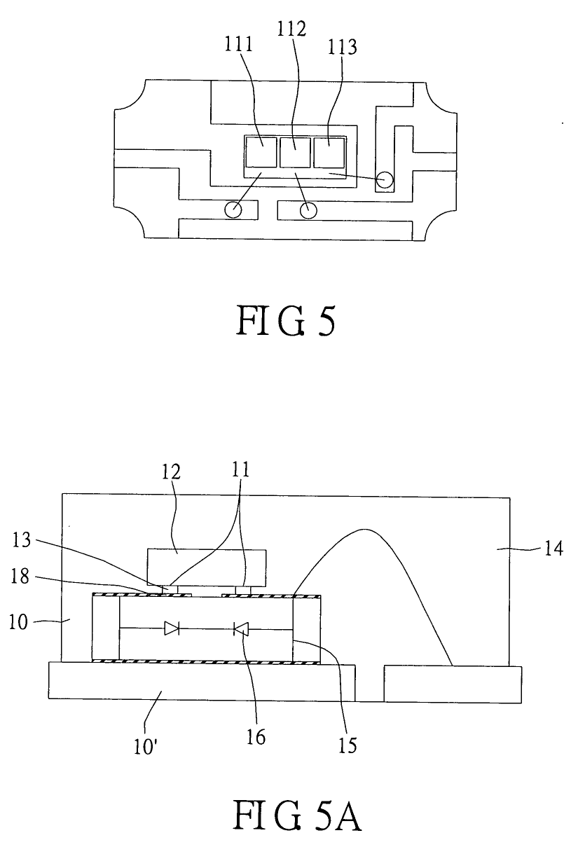

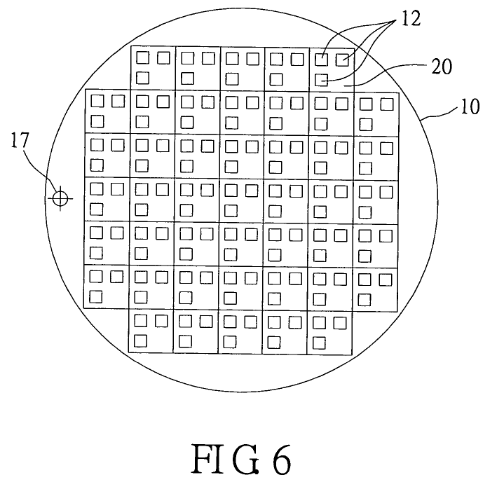

Please refer to FIGS. 4 to FIG. 6. FIG. 6 shows a wafer 10 with an orientation mark 17. FIGS. 4 and 5 have a conductive material 13 that is screen-printed upon the wafer 10. The thickness of the conductive material 13 is 10 μm to 50 μm. The crystal joint 11 can be located at the periphery, in the center or over the entire surface area. The top surface of the wafer 10 has an over voltage protection circuit 15 which is parallel to the electro-optical semiconductor grain 12. The over voltage protection circuit 15 is formed by cascading two opposite orientations over voltage protection diodes 16. The conductive material 13 is made with solder or silver paste.

The electro-optical semiconductor grain 12 can be used as an LED. As shown in FIG. 5, a plurality of red, green, blue, ultraviolet, or infrared ray semiconductor grains are set in a specific area to make an LED. The RGB semiconductor grain of the present embodiment can be manufactured by using the flip-chip method to produce an RGB grain module and electrically connecting it to the substrate 10′ by bonding it with wires (shows as in FIG. 5A) or packaging it into device as in FIG. 4.

In FIG. 4, the back surface of the wafer 10 has a soldering portion 22. As such, the wafer 10 can act as the substrate and bonding with wire is not needed. In FIG. 6 another embodiment of the present invention is shown. In this embodiment, the present invention can set the integrated circuit grains in a specific area and can be polycrystalline.

The present invention further comprises a highly polymeric packaging structure 14 surrounding the electro-optical semiconductor grains 12. The wafer 10 can also electrically connect to the electro-optical semiconductor by using a metal-metal eutectic or by using different melted metals such as gold-to-gold eutectic or gold to tin melting or tin-to-tin eutectic or melting.

Traditional PCB boards cannot function with lines that are thinner than 0.05 mm. However, wafers can function with a line width under 0.005 mm, thereby reducing the device's size drastically. An LED becomes brighter by reducing the distance between its individual grains. When this is done, the wafer substrate also dissipates heat more efficiently than traditional PCB boards thereby extending the product's user life.

The present invention uses Si wafer as a base (Si/SiC base), the Si base has a circuit thereon like a printed circuit board (PCB). The LED chips (RGB) are fixed on preservation positions of the Si base by the flip-chip method. As the circuits are connected to each other on the Si base, the entire array has a specific function. The Si base has high-density circuits for an IC process, which are greater than a printed circuit board (PCB), a metal lead-frame, a ceramic base and so on. The thermal expansion coefficient of the Si base is close to that of the LED chip. When the LED shines, the Si base suffers no stress due to a load board that causes a decrease in reliability, due to the thermal expansion coefficient of the Si base being close to that of the LED chip.

The array has a high number of pixels due to the chip's highly concentrated arrangement and greater than use surface mounted design (SMD) of the LEDs set on the printed circuit board (PCB). The array has reduced sight distance. Furthermore, the wafer 10 can cut different sized monitors. The monitors can cut a single unit LED to remove bad points thereon for producing a good rate.

The advantages of the present invention are as follows:

1. Better alignment and yield: the present invention is made by printing conductive materials and stacking electro-optical semiconductor grains onto the wafer thereby reducing alignment distortions and increasing yield.

2. Reduction in the device's size: the electro-optical semiconductor grains are stacked onto the wafer, so the present invention can be packaged in a wafer-level package.

3. Low cost processing equipment: the process can be easily implemented, as the equipment needed is both cheap and easily acquired.

4. Improved functionality: placing other circuits on the wafer such as over-voltage protection, voltage regulation, current regulation, noise filtering and electrical static discharge circuits.

5. Cutting different sized monitors. The monitors can cut a single unit LED to remove bad points thereon for producing a good rate.

6. The thermal expansion coefficient of the Si base is close to that of the LED chip. When the LED shines, the Si base suffers no stress due to a load board that causes a decrease in reliability, due to the thermal expansion coefficient of the Si base being close to that of the LED chip.

Although the present invention has been described with reference to the preferred embodiment thereof, it should be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A wafer-level electro-optical semiconductor manufacture fabrication method, further comprising:
preparing a wafer with a preservation position for covering jointed crystal grains;
daubing a plurality of conducting materials onto the preservation position;
stacking electro-optical semiconductor onto the conductive materials of the wafer;
packaging the electro-optical semiconductor with high polymeric materials to produce a semi-finished product;
cutting the semi-finished product to form different sized or a single unit electro-optical semiconductor mechanism.

2. The wafer-level electro-optical semiconductor manufacture fabrication method as claimed in claim 1, wherein the wafer has over-voltage protection, voltage regulation, current regulation, noise filtering and electrical static discharge circuits all electrically connected to the preservation position.

3. The wafer-level electro-optical semiconductor manufacture fabrication method as claimed in claim 1, wherein the semi-finished product is cut to form a single unit electro-optical semiconductor mechanism to remove bad points thereon.

4. The wafer-level electro-optical semiconductor manufacture fabrication method as claimed in claim 1, wherein the conductive materials are made by screen-printing or steel board printing.

5. The wafer-level electro-optical semiconductor manufacture fabrication method as claimed in claim 1, wherein the conduction materials are made of solder or silver paste.

6. The wafer-level electro-optical semiconductor manufacture fabrication method as claimed in claim 1, wherein the contact between the wafer and the electro-optical crystal grains can be made of a metal eutectic or melting different metals, a gold-tin, or a tin-tin melting connection.

7. The wafer-level electro-optical semiconductor manufacture fabrication method as claimed in claim 6, wherein the connection between the wafer and the electro-optical crystal grains can be a gold to gold eutectic, a gold to tin melting connection, or a tin to tin eutectic or a melting connection.
